(19) United States
(12) Patent Application Publication
(10) Pub. No.: US 2007/0146990 A1
(43) Pub. Date: Jun. 28, 2007

(54) HEAT DISSIPATING ASSEMBLY

(75) Inventor: MING-CHIH HSIEH, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,710

(22) Filed: Sep. 15, 2006

(30) Foreign Application Priority Data
Dec. 23, 2005 (CN) 200510121220.0

(51) Int. Cl. H05K 7/20

(52) U.S. Cl. 361/690

(57) ABSTRACT

A heat dissipating assembly mounted in an enclosure of an electronic device for dissipating heat for an electronic component of the electronic device, includes a heat sink attached to the electronic component of the electronic device, and a heat-conducting member connecting the enclosure of the electronic device and the heat sink so as to conducting heat from the heat sink to the enclosure.

### 1. FIELD OF THE INVENTION

The present invention relates to heat dissipating assemblies, and more particularly to a heat dissipating assembly effectively dissipating heat for an electronic component.

### 2. DESCRIPTION OF RELATED ART

During operation of an electronic component of an electronic device such as a central processing unit (CPU) of a computer, a large amount of heat is often produced. The heat must be quickly removed from the CPU to prevent unstable operation or damaged to the CPU. Typically, a heat sink is attached to an outer surface of the CPU to absorb the heat from the CPU. The heat absorbed by the heat sink is then dissipated to the surrounding air. Then the heat is conducted out of the computer.

However dissipating heat to air of the enclosure is slow and inefficient.

The present invention is desired to solve the above problem.

### SUMMARY OF THE INVENTION

In one preferred embodiment, a heat dissipating assembly mounted in an enclosure of an electronic device for dissipating heat for an electronic component of the electronic device, includes a heat sink attached to the electronic component, and a heat-conducting member connecting the enclosure of the electronic device to the heat sink so as to conducting heat from the heat sink to the enclosure.

Other advantages and novel features will become more apparent from the following detailed description of preferred embodiments when taken in conjunction with the accompanying drawings, in which:

### BRIEF DESCRIPTION OF THE DRAWINGS

FIG. 1 is a sketch view of a heat dissipating assembly mounted in an enclosure of an electronic device in accordance with a first preferred embodiment of the present invention;

FIG. 2 is a sketch view of a heat dissipating assembly mounted in the enclosure of an electronic device in accordance with a second preferred embodiment of the present invention; and

FIG. 3 is a sketch view of a heat dissipating assembly mounted in the enclosure of an electronic device in accordance with a third preferred embodiment of the present invention.

### DETAILED DESCRIPTION OF THE INVENTION

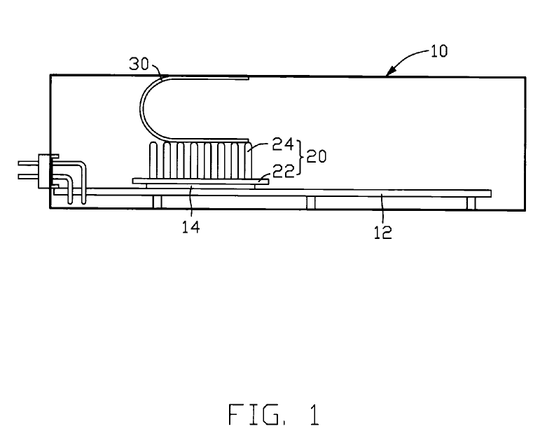

Referring to FIG. 1, in a preferred embodiment of the present invention, a heat dissipating assembly mounted in an enclosure 10 of an electronic device, such as a computer or a server, includes a heat sink 20, and a heat-conducting member 30.

A printed circuit board 12 is mounted in the enclosure 10. An electronic component 14, such as a CPU, is mounted to the printed circuit board 12.

The heat sink 20 includes a base 22. A plurality of fins 24 extends from the base 22. The heat sink 20 is mounted to the printed circuit board 12, and the base 22 of the heat sink 20 is pressed firmly against the electronic component 14.

The heat-conducting member 30 is generally U-shaped. One long side of the heat-conducting member 30 is pressed firmly against a top of the fins 24 of the heat sink 20, and another long side of the heat-conducting member 30 is pressed firmly against an inner surface of the enclosure 10.

The heat-conducting member 30 is made of heat-conductive material, such as aluminum, copper, and so on.

During operation of the electronic component 14 of an electronic device 10, a large amount of heat may be produced and absorbed by the heat sink 20. The heat absorbed by the heat sink 20 is then conducted to the enclosure 10 via the heat-conducting member 30 and the air in the enclosure 10. Then the heat is dissipated out of the enclosure 10.

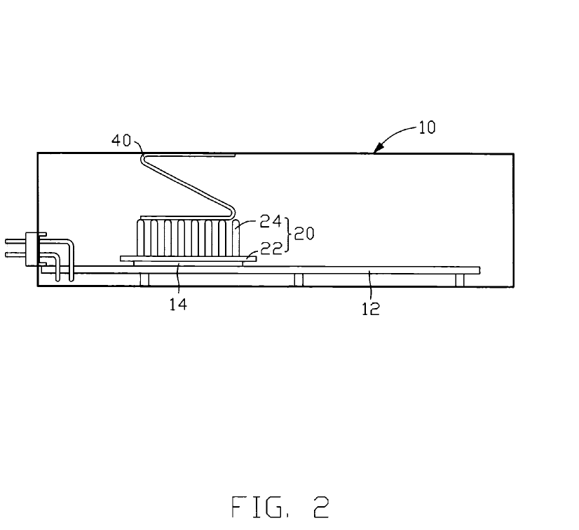

Referring to FIG. 2, a heat dissipating assembly in accordance with a second preferred embodiment of the present invention is shown. The main difference between the second preferred embodiment and the first preferred embodiment is that the heat-conducting member 30 is substituted by a generally N-shaped heat-conducting member 40.

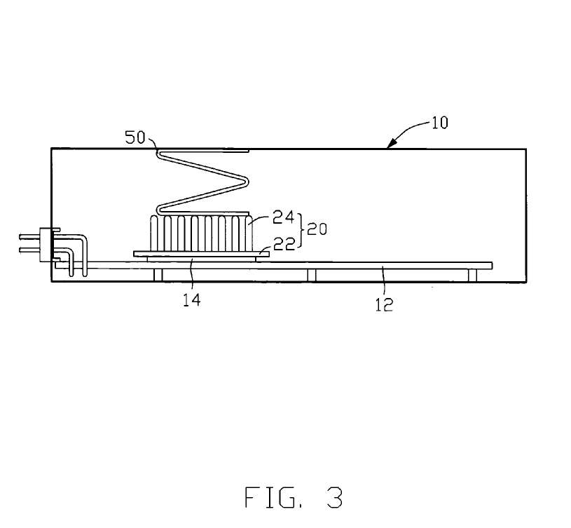

Referring to FIG. 3, a heat dissipating assembly in accordance with a third preferred embodiment of the present invention is shown. The main difference between the third preferred embodiment and the first preferred embodiment is that the heat-conducting member 30 is substituted by a generally M-shaped heat-conducting member 50.

It is believed that the present embodiments and their advantages will be understood from the foregoing description, and it will be apparent that various changes may be made thereto without departing from the spirit and scope of the invention or sacrificing all of their material advantages, the examples hereinbefore described merely being preferred or exemplary embodiments.

What is claimed is:

1. A heat dissipating assembly mounted in an enclosure of an electronic device for dissipating heat for an electronic component of the electronic device, the heat dissipating assembly comprising:
a heat sink configured for attachment to the electronic component of the electronic device; and
a heat-conducting member configured for connecting the enclosure of the electronic device to the heat sink so as to conducting heat from the heat sink to the enclosure.

2. The heat dissipating assembly as claimed in claim 1, wherein the heat-conducting member comprises two long sides, one long side contacts the heat sink, the other long side contacts the enclosure of the electronic device.

3. The heat dissipating assembly as claimed in claim 2, wherein the heat-conducting member is generally U-shaped.

4. The heat dissipating assembly as claimed in claim 2, wherein the heat-conducting member is generally N-shaped.

5. The heat dissipating assembly as claimed in claim 2, wherein the heat-conducting member is generally M-shaped.

6. The heat dissipating assembly as claimed in claim 1, wherein the heat-conducting member is made of heat-conductive material.

7. An assembly comprising:
an enclosure;
an electronic component mounted in the enclosure;
a heat sink attached to the electronic component; and
a heat-conducting member placed in the enclosure and connecting the enclosure to the heat sink.

8. The heat dissipating assembly as claimed in claim 7, wherein the heat-conducting member comprises two long sides, one long side contacts the heat sink, the other long side contacts the enclosure of the electronic device.

9. The heat dissipating assembly as claimed in claim 8, wherein the heat-conducting member is generally U-shaped.

10. The heat dissipating assembly as claimed in claim 8, wherein the heat-conducting member is generally N-shaped.

11. The heat dissipating assembly as claimed in claim 8, wherein the heat-conducting member is generally M-shaped.

12. The heat dissipating assembly as claimed in claim 7, wherein the heat-conducting member is made of heat-conductive material.
